(19) United States
(12) Patent Application Publication
(10) Pub. No.: US 2024/0154038 A1
(43) Pub. Date: May 9, 2024

(54) SEMICONDUCTOR DEVICE, DISPLAY DEVICE AND METHOD FOR MANUFACTURING SEMICONDUCTOR DEVICE

(71) Applicant: Sharp Display Technology Corporation, Kameyama City (JP)

(72) Inventors: Tetsuo KIKUCHI, Kameyama City (JP); Tohru DAITOH, Kameyama City (JP); Masahiko SUZUKI, Kameyama City (JP); Setsuji NISHIMIYA, Kameyama City (JP); Hitoshi TAKAHATA, Kameyama City (JP)

(21) Appl. No.: 18/378,165

(22) Filed: Oct. 10, 2023

Related U.S. Application Data
(60) Provisional application No. 63/423,581, filed on Nov. 8, 2022.

(51) Int. Cl. H01L 29/786; G02F 1/1368; H01L 29/417; H01L 29/66; H10K 59/121

(52) U.S. Cl. CPC H01L 29/7869; G02F 1/1368; H01L 29/41733; H01L 29/6675; H01L 29/78696; H10K 59/1213

(57) ABSTRACT

A semiconductor device includes a first TFT of a first conductivity type and a second TFT of a second conductivity type. The first TFT includes a first semiconductor layer made of an oxide semiconductor material of the first conductivity type, a first gate insulating layer provided on the first semiconductor layer, a first gate electrode located opposite to a channel region of the first semiconductor layer with the first gate insulating layer interposed therebetween, and a first source electrode. The second TFT includes a second semiconductor layer made of an oxide semiconductor material of the second conductivity type or a transparent semiconductor material of the second conductivity type, a second gate insulating layer provided on the second semiconductor layer, a second gate electrode located opposite to a channel region of the second semiconductor layer with the second gate insulating layer interposed therebetween, and a second source electrode. The first gate insulating layer includes a first layer and a second layer provided on the first layer. The second layer of the first gate insulating layer and the second gate insulating layer are provided in the same layer.

### BACKGROUND

### 1. Technical Field

The present invention relates to a semiconductor device and a display device. The present invention also relates to a method of manufacturing a semiconductor device.

### 2. Description of the Related Art

In recent years, using an oxide semiconductor as a material of the active layer of thin film transistors (hereinafter, referred to as “TFTs”), instead of amorphous silicon and polycrystalline silicon, has been proposed. A TFT which includes an oxide semiconductor film as the active layer is referred to as “oxide semiconductor TFT”. Patent Document No. 1 (Japanese Laid-Open Patent Publication No. 2012-134475) discloses an active matrix substrate in which an In—Ga—Zn—O based semiconductor film is used for the active layer of TFTs.

The oxide semiconductor has higher mobility than the amorphous silicon. Therefore, oxide semiconductor TFTs are capable of higher speed operation than amorphous silicon TFTs. Further, oxide semiconductor films can be formed through a simpler and more convenient process than polycrystalline silicon films and are therefore applicable to devices which require large surfaces.

### SUMMARY

Many oxide semiconductors currently in practical use as active layer materials for TFTs are n-type (n-channel type) although, recently, some p-type (p-channel type) oxide semiconductors have been newly proposed as the active layer materials. Some known oxide semiconductors have wide bandgaps and are transparent. Also, a high-mobility, p-type transparent semiconductor which is not an oxide has been proposed. Hereinafter, a TFT which includes a transparent semiconductor film as the active layer is referred to as “transparent semiconductor TFT”. There is such a case that an oxide semiconductor TFT is a transparent semiconductor TFT. It is expected that when an n-type oxide semiconductor TFT and a p-type oxide semiconductor TFT (or transparent semiconductor TFT) are united into a complementary type configuration, whereby a CMOS (Complementary Metal-Oxide Semiconductor) structure circuit is formed, lower voltages and reduction in power consumption can be achieved.

However, a suitable configuration of the CMOS structure that includes an n-type oxide semiconductor TFT and a p-type oxide semiconductor TFT (or transparent semiconductor TFT) has not yet been established.

An embodiment of the present invention was conceived in view of the above-described problems. An object of the embodiment of the present invention is to suitably realize the CMOS structure that includes an n-type oxide semiconductor TFT and a p-type oxide semiconductor TFT (or transparent semiconductor TFT).

This specification discloses a semiconductor device, a display device, and a semiconductor device manufacturing method as set forth in the following items.

[Item 1]

A complementary semiconductor device comprising:
a substrate;
a first thin film transistor of a first conductivity type, the first thin film transistor being supported by the substrate; and
a second thin film transistor of a second conductivity type that is different from the first conductivity type, the second thin film transistor being supported by the substrate,
wherein the first thin film transistor includes
   a first semiconductor layer made of an oxide semiconductor material of the first conductivity type, the first semiconductor layer including a first channel region and a first source region and a first drain region located on opposite sides of the first channel region,
   a first gate insulating layer provided on the first semiconductor layer,
   a first gate electrode located opposite to the first channel region with the first gate insulating layer interposed therebetween, and
   a first source electrode electrically coupled with the first source region,
wherein the second thin film transistor includes
   a second semiconductor layer made of an oxide semiconductor material of the second conductivity type or a transparent semiconductor material of the second conductivity type, the second semiconductor layer including a second channel region and a second source region and a second drain region located on opposite sides of the second channel region,
   a second gate insulating layer provided on the second semiconductor layer,
   a second gate electrode located opposite to the second channel region with the second gate insulating layer interposed therebetween, and
   a second source electrode electrically coupled with the second source region,
wherein the first gate insulating layer includes a first layer and a second layer provided on the first layer, and
wherein the second layer of the first gate insulating layer and the second gate insulating layer are provided in the same layer.

[Item 2]

The semiconductor device as set forth in Item 1, wherein
the first gate electrode and the second gate electrode are provided in the same layer, and
the first source electrode and the second source electrode are provided in the same layer.

[Item 3]

The semiconductor device as set forth in Item 1 or 2 further comprising an insulating layer provided in the same layer as the first layer of the first gate insulating layer,
wherein the second semiconductor layer is provided on the insulating layer.

[Item 4]

The semiconductor device as set forth in any of Items 1 to 3, wherein
the first thin film transistor includes a first drain electrode electrically coupled with the first drain region,
the second thin film transistor includes a second drain electrode electrically coupled with the second drain region,
the first source electrode, the first drain electrode, the second source electrode and the second drain electrode are provided in the same layer.

[Item 5]

The semiconductor device as set forth in Item 4 further comprising an interlayer insulating layer provided so as to cover the first gate electrode and the second gate electrode,
wherein the first source electrode, the first drain electrode, the second source electrode and the second drain electrode are provided on the interlayer insulating layer.

[Item 6]

The semiconductor device as set forth in any of Items 1 to 5, wherein the first conductivity type is n-type, and the second conductivity type is p-type.

[Item 7]

The semiconductor device as set forth in Item 6, wherein the first semiconductor layer includes an In—Ga—Zn—O based semiconductor.

[Item 8]

The semiconductor device as set forth in any of Items 1 to 5, wherein the first conductivity type is p-type, and the second conductivity type is n-type.

[Item 9]

The semiconductor device as set forth in Item 8, wherein the second semiconductor layer includes an In—Ga—Zn—O based semiconductor.

[Item 10]

The semiconductor device as set forth in any of Items 1 to 9 further comprising a capacitive element, the capacitive element including
a first capacitive electrode that is an extended part of the first semiconductor layer,
a second capacitive electrode that is an extended part of the second semiconductor layer, and
a capacitive insulating layer provided between the first capacitive electrode and the second capacitive electrode, the capacitive insulating layer being provided in the same layer as the first layer of the first gate insulating layer.

[Item 11]

The semiconductor device as set forth in any of Items 1 to 10, wherein the semiconductor device is an active matrix substrate for a display device that includes a display region defined by a plurality of pixel regions and a peripheral region lying around the display region.

[Item 12]

The semiconductor device as set forth in Item 11 further comprising a gate driver circuit provided in the peripheral region,
wherein the gate driver circuit includes the first thin film transistor and the second thin film transistor.

[Item 13]

The semiconductor device as set forth in Item 11 further comprising a demultiplexer circuit provided in the peripheral region,
wherein the demultiplexer circuit includes the first thin film transistor and the second thin film transistor.

[Item 14]

A display device comprising the semiconductor device as set forth in any of Items 11 to 13 as the active matrix substrate.

[Item 15]

The display device as set forth in Item 14, wherein the display device is a liquid crystal display device.

[Item 16]

The display device as set forth in Item 14, wherein the display device is an organic EL display device.

[Item 17]

A method of manufacturing a complementary semiconductor device, the complementary semiconductor device including
a substrate,
a first thin film transistor of a first conductivity type, the first thin film transistor being supported by the substrate, and
a second thin film transistor of a second conductivity type that is different from the first conductivity type, the second thin film transistor being supported by the substrate,
the first thin film transistor including
   a first semiconductor layer made of an oxide semiconductor material of the first conductivity type, the first semiconductor layer including a first channel region and a first source region and a first drain region located on opposite sides of the first channel region,
   a first gate insulating layer provided on the first semiconductor layer,
   a first gate electrode located opposite to the first channel region with the first gate insulating layer interposed therebetween, and
   a first source electrode electrically coupled with the first source region, and
the second thin film transistor including
   a second semiconductor layer made of an oxide semiconductor material of the second conductivity type or a transparent semiconductor material of the second conductivity type, the second semiconductor layer including a second channel region and a second source region and a second drain region located on opposite sides of the second channel region,
   a second gate insulating layer provided on the second semiconductor layer,
   a second gate electrode located opposite to the second channel region with the second gate insulating layer interposed therebetween, and
   a second source electrode electrically coupled with the second source region,
the method comprising:
(A) depositing a first semiconductor film on the substrate and thereafter patterning the first semiconductor film, thereby forming the first semiconductor layer;
(B) after (A), depositing a first insulating film so as to cover the first semiconductor layer, the first insulating film including a region which is to become a first layer that is a part of the first gate insulating layer;
(C) after (B), depositing a second semiconductor film and thereafter patterning the second semiconductor film, thereby forming the second semiconductor layer;
(D) after (C), depositing a second insulating film, the second insulating film including a region which is to become a second layer that is another part of the first gate insulating layer and a region which is to become the second gate insulating layer;
(E) after (D), depositing a first electrically-conductive film and thereafter patterning the first electrically-conductive film, thereby forming the first gate electrode and the second gate electrode;
(F) after (E), forming an interlayer insulating layer so as to cover the first gate electrode and the second gate electrode; and
(G) after (F), depositing a second electrically-conductive film on the interlayer insulating layer and thereafter patterning the second electrically-conductive film, thereby forming the first source electrode and the second source electrode.

[Item 18]

The method as set forth in Item 17, wherein
the first thin film transistor includes a first drain electrode electrically coupled with the first drain region,
the second thin film transistor includes a second drain electrode electrically coupled with the second drain region, and
(G) includes forming the first drain electrode and the second drain electrode together with the first source electrode and the second source electrode.

[Item 19]

The method as set forth in Item 17 or 18, wherein the first conductivity type is n-type, and the second conductivity type is p-type.

[Item 20]

The method as set forth in Item 17 or 18, wherein the first conductivity type is p-type, and the second conductivity type is n-type.

According to an embodiment of the present invention, it is possible to suitably realize the CMOS structure that includes an n-type oxide semiconductor TFT and a p-type oxide semiconductor TFT (or transparent semiconductor TFT).

### BRIEF DESCRIPTION OF THE DRAWINGS

FIG. 1 is a cross-sectional view schematically showing a semiconductor device 100 according to an embodiment of the present invention.

FIG. 2A is a cross-sectional view for illustrating a step of the manufacturing method of the semiconductor device 100.

FIG. 2B is a cross-sectional view for illustrating a step of the manufacturing method of the semiconductor device 100.

FIG. 2C is a cross-sectional view for illustrating a step of the manufacturing method of the semiconductor device 100.

FIG. 2D is a cross-sectional view for illustrating a step of the manufacturing method of the semiconductor device 100.

FIG. 2E is a cross-sectional view for illustrating a step of the manufacturing method of the semiconductor device 100.

FIG. 2F is a cross-sectional view for illustrating a step of the manufacturing method of the semiconductor device 100.

FIG. 2G is a cross-sectional view for illustrating a step of the manufacturing method of the semiconductor device 100.

FIG. 2H is a cross-sectional view for illustrating a step of the manufacturing method of the semiconductor device 100.

FIG. 2I is a cross-sectional view for illustrating a step of the manufacturing method of the semiconductor device 100.

FIG. 2J is a cross-sectional view for illustrating a step of the manufacturing method of the semiconductor device 100.

FIG. 2K is a cross-sectional view for illustrating a step of the manufacturing method of the semiconductor device 100.

FIG. 3A is a cross-sectional view schematically showing the semiconductor device 100.

FIG. 3B is a cross-sectional view schematically showing the semiconductor device 100.

FIG. 4 is a cross-sectional view schematically showing another semiconductor device 100A according to an embodiment of the present invention.

FIG. 5 is a cross-sectional view schematically showing still another semiconductor device 100B according to an embodiment of the present invention.

FIG. 6 is a cross-sectional view schematically showing still another semiconductor device 200 according to an embodiment of the present invention.

FIG. 7A is a cross-sectional view schematically showing the semiconductor device 200.

FIG. 7B is a cross-sectional view schematically showing the semiconductor device 200.

FIG. 8 is a cross-sectional view schematically showing still another semiconductor device 200A according to an embodiment of the present invention.

FIG. 9 is a cross-sectional view schematically showing still another semiconductor device 200B according to an embodiment of the present invention.

FIG. 10 is a plan view schematically showing an active matrix substrate 1000.

FIG. 11 is an equivalent circuit diagram of a plurality of pixels PIX included in a liquid crystal display device 1100.

FIG. 12 is an equivalent circuit diagram of a single pixel PIX of an organic EL display device 1200.

### DETAILED DESCRIPTION

Hereinafter, embodiments of the present invention are described with reference to the drawings. The present invention is not limited to the following embodiments. In the drawings mentioned below, components which have substantially the same function are indicated with a common reference numeral, and the description thereof is sometimes omitted. For the sake of clarity of description, in the drawings mentioned below, the configuration is shown in a simplified or schematic form, or some components are sometimes omitted. The dimensional ratios between components shown in the drawings are not necessarily equal to actual dimensional ratios.

### Embodiment 1

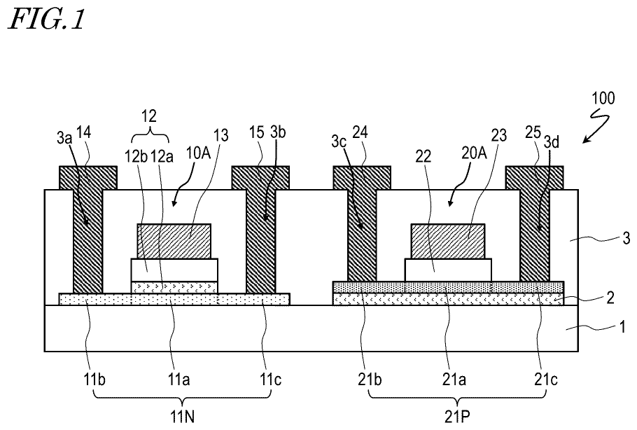

A complementary semiconductor device 100 of the present embodiment is described with reference to FIG. 1. FIG. 1 is a cross-sectional view schematically showing the semiconductor device 100.

As shown in FIG. 1, the semiconductor device 100 includes a substrate 1, a first thin film transistor 10A of the first conductivity type (hereinafter, referred to as “first TFT 10A”), and a second thin film transistor 20A of the second conductivity type that is different from the first conductivity type (hereinafter, referred to as “second TFT 20A”). In the present embodiment, the first TFT 10A is n-type, and the second TFT 20A is p-type. The first TFT 10A is an oxide semiconductor TFT, and the second TFT 20A is an oxide semiconductor TFT or a transparent semiconductor TFT.

The substrate 1 is insulative and typically transparent. The substrate 1 is, for example, a glass substrate or a plastic substrate.

The first TFT 10A is supported by the substrate 1 and has a top gate structure. The first TFT 10A includes a first semiconductor layer 11N, a first gate insulating layer 12, a first gate electrode 13, a first source electrode 14 and a first drain electrode 15.

The first semiconductor layer 11N is made of an n-type oxide semiconductor material. The first semiconductor layer 11N includes a channel region 11a, and a source region 11b and a drain region 11c located on opposite sides of the channel region 11a.

The first gate insulating layer 12 is provided on the first semiconductor layer 11N. The first gate insulating layer 12 includes the first layer (lower layer) 12a that is in contact with the first semiconductor layer 11N and the second layer (upper layer) 12b provided on the first layer 12a. That is, the first gate insulating layer 12 has a multilayer structure.

The first gate electrode 13 is provided opposite to the channel region 11a of the first semiconductor layer 11N with the first gate insulating layer 12 interposed therebetween. The first source electrode 14 is electrically coupled with the source region 11b of the first semiconductor layer 11N. The first drain electrode 15 is electrically coupled with the drain region 11c of the first semiconductor layer 11N.

The second TFT 20A is supported by the substrate 1 and has a top gate structure as the first TFT 10A is. The second TFT 20A includes a second semiconductor layer 21P, a second gate insulating layer 22, a second gate electrode 23, a second source electrode 24 and a second drain electrode 25.

The second semiconductor layer 21P is made of a p-type oxide semiconductor material or a p-type transparent semiconductor material. The second semiconductor layer 21P includes a channel region 21a, and a source region 21b and a drain region 21c located on opposite sides of the channel region 21a. The second semiconductor layer 21P is provided on an insulating layer 2 that is provided in the same layer as the first layer 12a of the first gate insulating layer 12 (i.e., that is formed together with the first layer 12a in the step of forming the first layer 12a).

The second gate insulating layer 22 is provided on the second semiconductor layer 21P and is in contact with the second semiconductor layer 21P. The second gate insulating layer 22 is provided in the same layer as the second layer (upper layer) 12b of the first gate insulating layer 12 (i.e., the second gate insulating layer 22 is formed together with the second layer 12b in the step of forming the second layer 12b).

The second gate electrode 23 is provided opposite to the channel region 21a of the second semiconductor layer 21P with the second gate insulating layer 22 interposed therebetween. The second gate electrode 23 is provided in the same layer as the first gate electrode 13 (i.e., the second gate electrode 23 is formed together with the first gate electrode 13 in the step of forming the first gate electrode 13).

The second source electrode 24 is electrically coupled with the source region 21b of the second semiconductor layer 21P. The second drain electrode 25 is electrically coupled with the drain region 21c of the second semiconductor layer 21P. The second source electrode 24 and the second drain electrode 25 are provided in the same layer as the first source electrode 14 and the first drain electrode 15 (i.e., the second source electrode 24 and the second drain electrode 25 are formed together with the first source electrode 14 and the first drain electrode 15 in the step of forming the first source electrode 14 and the first drain electrode 15).

The interlayer insulating layer 3 is provided so as to cover the first gate electrode 13, the second gate electrode 23, and the like. The first source electrode 14, the first drain electrode 15, the second source electrode 24 and the second drain electrode 25 are provided on the interlayer insulating layer 3. The interlayer insulating layer 3 has the first contact hole 3a, the second contact hole 3b, the third contact hole 3c and the fourth contact hole 3d. In the first contact hole 3a, the first source electrode 14 is electrically coupled with the source region 11b of the first semiconductor layer 11N. In the second contact hole 3b, the first drain electrode 15 is electrically coupled with the drain region 11c of the first semiconductor layer 11N. In the third contact hole 3c, the second source electrode 24 is electrically coupled with the source region 21b of the second semiconductor layer 21P. In the fourth contact hole 3d, the second drain electrode 25 is electrically coupled with the drain region 21c of the second semiconductor layer 21P.

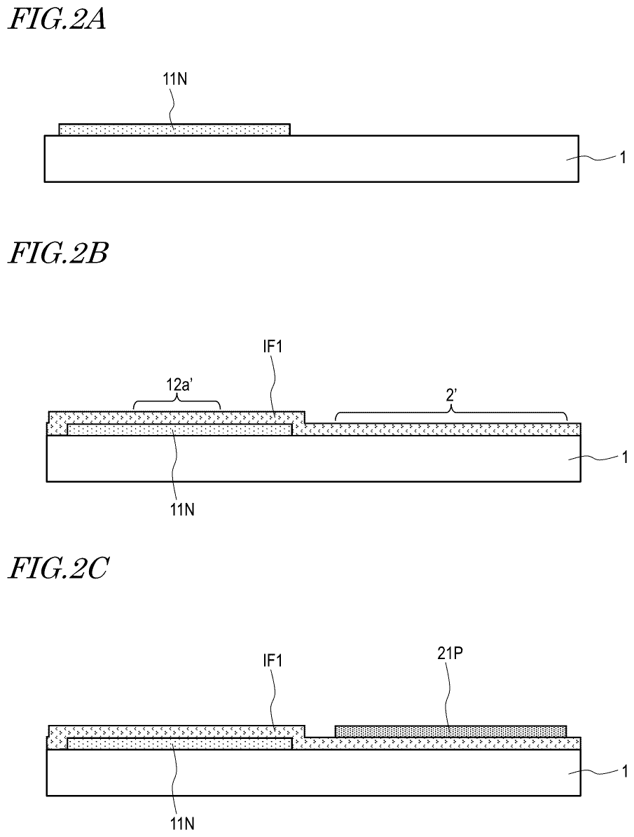

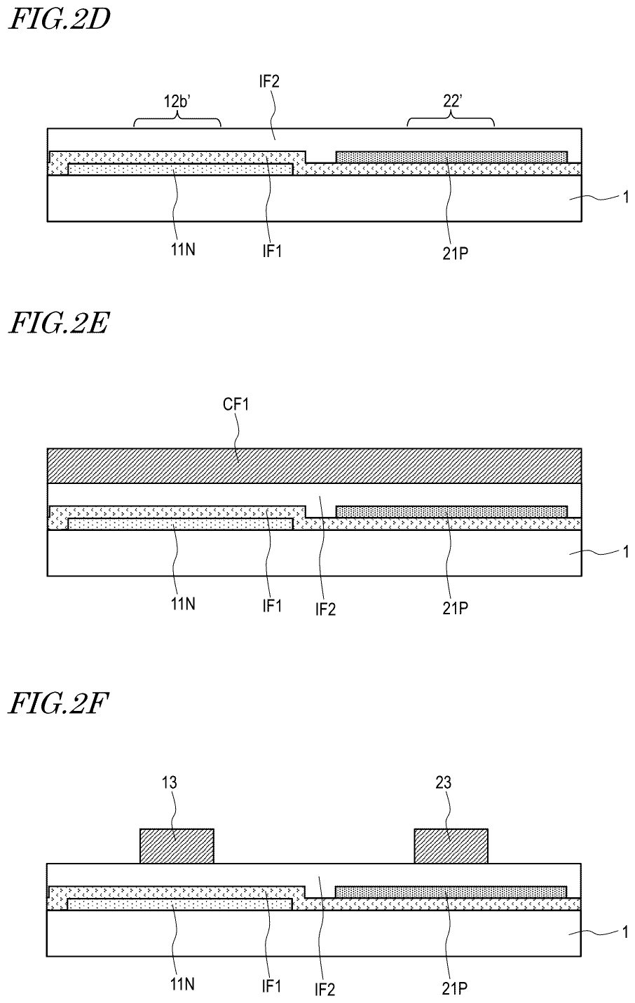

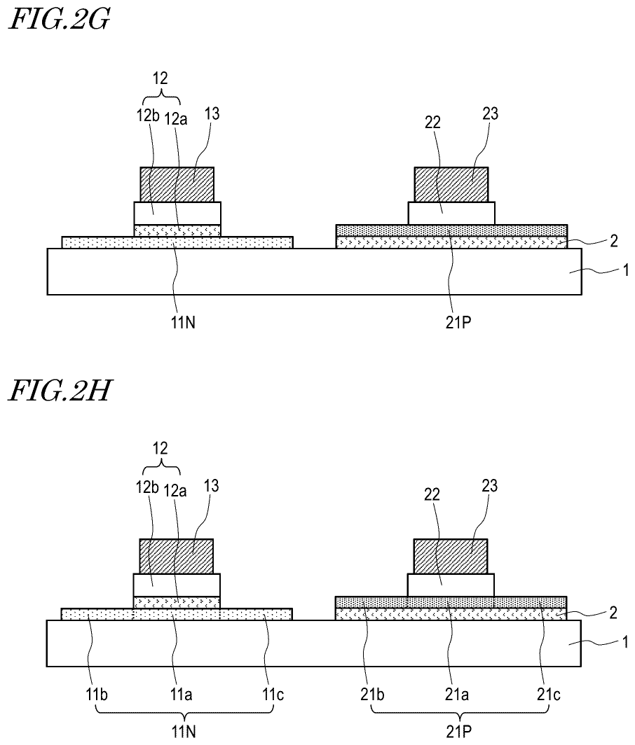

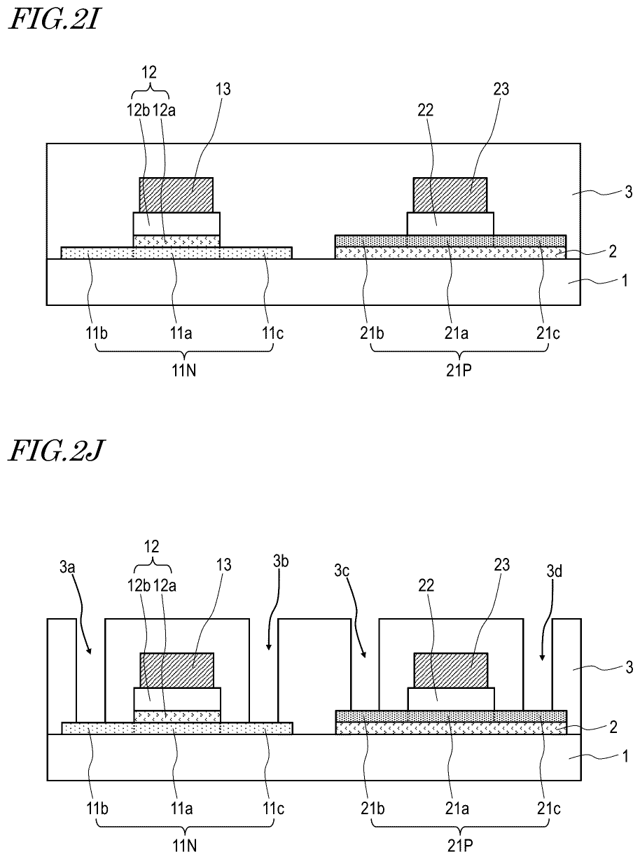

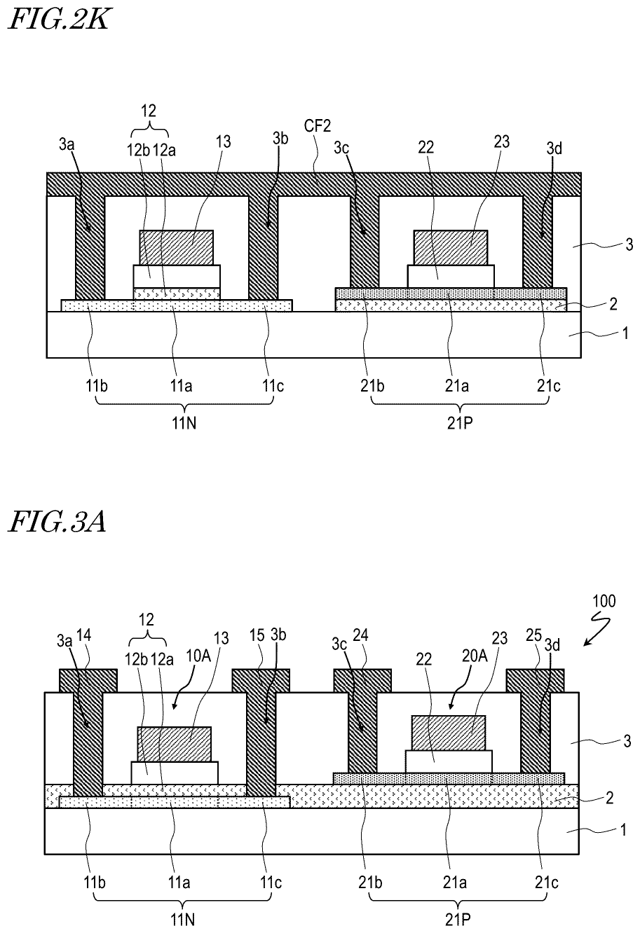

Next, a manufacturing method of the semiconductor device 100 is described with reference to FIG. 2A, FIG. 2B, FIG. 2C, FIG. 2D, FIG. 2E, FIG. 2F, FIG. 2G, FIG. 2H, FIG. 2I, FIG. 2J and FIG. 2K. FIG. 2A, FIG. 2B, FIG. 2C, FIG. 2D, FIG. 2E, FIG. 2F, FIG. 2G, FIG. 2H, FIG. 2I, FIG. 2J and FIG. 2K are cross-sectional views illustrating the steps of the manufacturing method of the semiconductor device 100.

Firstly, as shown in FIG. 2A, an n-type first semiconductor layer 11N is formed on the substrate 1. Specifically, the first semiconductor layer 11N can be formed by depositing a first semiconductor film (thickness: for example, 15 nm to 200 nm inclusive) on the substrate 1 and thereafter patterning the first semiconductor film.

As the substrate 1, for example, a glass substrate, a silicon substrate, a heat-resistant plastic substrate (resin substrate), or the like, can be used.

Deposition of the first semiconductor film can be realized by, for example, sputtering. Patterning of the first semiconductor film can be realized by, for example, wet etching. The material of the first semiconductor film is not particularly limited but may be, for example, an In—Ga—Zn—O based semiconductor.

Then, as shown in FIG. 2B, a first insulating film IF1 (thickness: for example, 20 nm to 150 nm inclusive) is deposited so as to cover the first semiconductor layer 11N. The first insulating film IF1 includes a region 12a′ which is to become the first layer 12a of the first gate insulating layer 12 (a part of the first gate insulating layer 12) and a region 2′ which is to become an insulating layer 2 interposed between the second semiconductor layer 21P and the substrate 1.

Deposition of the first insulating film IF1 can be realized by, for example, CVD. As the material of the first insulating film IF1, a silicon oxide (SiO₂), a silicon nitride (SiNx), a silicon oxynitride (SiOxNy; x>y), a silicon nitroxide (SiNxOy; x>y), an aluminum oxide (Al₂O₃), a tantalum oxide (Ta₂O₅), or the like, can be appropriately used. The first insulating film IF1 may have a multilayer structure.

Subsequently, as shown in FIG. 2C, a p-type second semiconductor layer 21P is formed on the first insulating film IF1. Specifically, the second semiconductor layer 21P can be formed by depositing a second semiconductor film (thickness: for example, 20 nm to 200 nm inclusive) on the first insulating film IF1 and thereafter patterning the second semiconductor film.

Deposition of the second semiconductor film can be realized by, for example, sputtering. Patterning of the second semiconductor film can be realized by, for example, wet etching. The material of the second semiconductor film is not particularly limited but may be, for example, SnO.

Thereafter, a second layer 12b of the first gate insulating layer 12, a second gate insulating layer 22, a first gate electrode 13 and a second gate electrode 23 are formed.

Specifically, firstly, as shown in FIG. 2D, a second insulating film IF2 (thickness: for example, 80 nm to 250 nm inclusive) is deposited on the first insulating film IF1 and the second semiconductor layer 21P. The second insulating film IF2 includes a region 12b′ which is to become the second layer 12b of the first gate insulating layer 12 (another part of the first gate insulating layer 12) and a region 22′ which is to become the second gate insulating layer 22.

Deposition of the second insulating film IF2 can be realized by, for example, CVD. As the material of the second insulating film IF2, an aluminum oxide (Al₂O₃), a tantalum oxide (Ta₂O₅), a silicon oxide (SiO₂), a silicon oxynitride (SiOxNy; x>y), or the like, can be appropriately used. The second insulating film IF2 may have a multilayer structure.

Then, as shown in FIG. 2E, a first electrically-conductive film (electrically-conductive film for gate) CF1 (thickness: for example, 50 nm to 500 nm inclusive) is deposited on the second insulating film IF2. Deposition of the first electrically-conductive film CF1 can be realized by, for example, sputtering. As the material of the first electrically-conductive film CF1, aluminum (Al), chromium (Cr), copper (Cu), tantalum (Ta), titanium (Ti), molybdenum (Mo) or tungsten (W), or an alloy material including such elements can be used. The first electrically-conductive film CF1 may have a multilayer structure. The multilayer structure can be, for example, a three-layer structure of titanium layer/aluminum layer/titanium layer or a three-layer structure of molybdenum layer/aluminum layer/molybdenum layer. As a matter of course, the multilayer structure is not limited to a three-layer structure but may be a two-layer structure or a multilayer structure consisting of four or more layers.

Subsequently, as shown in FIG. 2F, the first electrically-conductive film CF1 is patterned, whereby a first gate electrode 13 and a second gate electrode 23 are formed. Patterning of the first electrically-conductive film CF1 can be realized by, for example, wet etching or dry etching.

Thereafter, as shown in FIG. 2G, the second insulating film IF2 is patterned, whereby a second layer 12b of the first gate insulating layer 12 and a second gate insulating layer 22 are formed. Patterning of the second insulating film IF2 can be realized by, for example, dry etching. In the example shown in FIG. 2G, in this step, the first insulating film IF1 is also patterned so as to be separated into the first layer 12a of the first gate insulating layer 12 and the insulating layer 2.

Then, a resistance reduction treatment is performed on the first semiconductor layer 11N and the second semiconductor layer 21P using the first gate electrode 13 and the second gate electrode 23 as masks. The resistance reduction treatment is, for example, a plasma treatment. By this resistance reduction treatment, as shown in FIG. 2H, regions of the first semiconductor layer 11N which do not underlie the first gate electrode 13 change into low-resistance regions (source region 11b and drain region 11c) whose specific resistance is lower than that of a region of the first semiconductor layer 11N which underlies the first gate electrode 13 (channel region 11a). Also, regions of the second semiconductor layer 21P which do not underlie the second gate electrode 23 change into low-resistance regions (source region 21b and drain region 21c) whose specific resistance is lower than that of a region of the second semiconductor layer 21P which underlies the second gate electrode 23 (channel region 21a).

Subsequently, as shown in FIG. 2I, an interlayer insulating layer 3 (thickness: for example, 100 nm to 500 nm inclusive) is formed so as to cover the first gate electrode 13 and the second gate electrode 23. The interlayer insulating layer 3 can be formed by, for example, CVD. As the material of the interlayer insulating layer 3, for example, a silicon oxide, a silicon nitride, a silicon oxynitride or a silicon nitroxide can be used. The interlayer insulating layer 3 may have a multilayer structure.

Then, as shown in FIG. 2J, a first contact hole 3a and a second contact hole 3b are formed in the interlayer insulating layer 3 such that the source region 11b and the drain region 11c of the first semiconductor layer 11N are partially exposed, while a third contact hole 3c and a fourth contact hole 3d are also formed in the interlayer insulating layer 3 such that the source region 21b and the drain region 21c of the second semiconductor layer 21P are partially exposed. Formation of the first, second, third and fourth contact holes 3a, 3b, 3c and 3d can be realized by a photolithography process (including, for example, a dry etching step).

Subsequently, as shown in FIG. 2K, a second electrically-conductive film (electrically-conductive film for source) CF2 (thickness: for example, 50 nm to 500 nm inclusive) is deposited on the interlayer insulating layer 3. Deposition of the second electrically-conductive film CF2 can be realized by, for example, sputtering. As the material of the second electrically-conductive film CF2, for example, the examples previously described as the material of the first electrically-conductive film CF1 can be used. The second electrically-conductive film CF2 may have a multilayer structure as the first electrically-conductive film CF1 does.

Thereafter, the second electrically-conductive film CF2 is patterned, whereby a first source electrode 14, a first drain electrode 15, a second source electrode 24 and a second drain electrode 25 are formed. Patterning of the second electrically-conductive film CF2 can be realized by, for example, wet etching or dry etching. Through the above-described process, the semiconductor device 100 shown in FIG. 1 is manufactured.

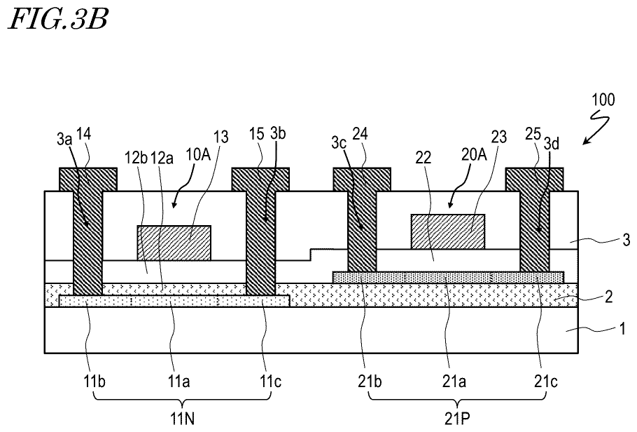

In the example described herein, while the second insulating film IF2 is patterned, the first insulating film IF1 is also patterned so as to be separated into the first layer 12a of the first gate insulating layer 12 and the insulating layer 2 although, as shown in FIG. 3A, in the complete semiconductor device 100, the first layer 12a of the first gate insulating layer 12 and the insulating layer 2 may be continuous. With some materials of the first insulating film IF1 and the second insulating film IF2 or some patterning methods, there is a probability that the first insulating film IF1 will not be separated into the first layer 12a of the first gate insulating layer 12 and the insulating layer 2 in the step of patterning the second insulating film IF2. For example, when the first insulating film IF1 is a silicon oxide film and the second insulating film IF2 has a multilayer structure including an aluminum oxide layer as the lower layer and a silicon oxide layer as the upper layer, there is a probability that the first insulating film IF1 will not be separated into the first layer 12a of the first gate insulating layer 12 and the insulating layer 2.

Alternatively, as shown in FIG. 3B, none of the first insulating film IF1 and the second insulating film IF2 may be patterned such that the first layer 12a of the first gate insulating layer 12 and the insulating layer 2 are continuous while the second layer 12b of the first gate insulating layer 12 and the second gate insulating layer 22 are continuous.

As previously described, the semiconductor device 100 of the present embodiment includes the first TFT 10A that is an n-type oxide semiconductor TFT and the second TFT 20A that is a p-type oxide semiconductor TFT (or p-type transparent semiconductor TFT) and, therefore, by using these TFTs in forming a CMOS structure circuit, lower voltages and reduction in power consumption can be achieved. Further, since both the first TFT 10A and the second TFT 20A have a top gate structure, the TFT characteristics and the reliability are excellent as compared with a case where an n-type TFT of a bottom gate structure and a p-type TFT of a bottom gate structure are used. Further, since a part (first layer) 12a of the first gate insulating layer 12 which is in contact with the first semiconductor layer 11N and the second gate insulating layer 22 that is in contact with the second semiconductor layer 21P are formed in different layers, the n-type oxide semiconductor TFT and the p-type oxide semiconductor TFT (or p-type transparent semiconductor TFT) can use different materials in forming the gate insulating films that are in contact with the semiconductor layers, i.e., can employ materials suitable to the respective gate insulating films.

The semiconductor device 100 of the present embodiment can be manufactured using a relatively small number of masks and, therefore, the manufacture cost can be reduced. For example, in the manufacturing method previously described with reference to FIG. 2A, FIG. 2B, FIG. 2C, FIG. 2D, FIG. 2E, FIG. 2F, FIG. 2G, FIG. 2H, FIG. 2I, FIG. 2J and FIG. 2K, the number of masks required is five (5). On the other hand, in the case where a CMOS structure is formed using n-type TFTs and p-type TFTs which have an LIPS (low-temperature polysilicon) layer as the active layer, the number of masks required before completion of the step of separating the source electrode and the drain electrode is usually eight (8).

Further, in the semiconductor device 100 of the present embodiment, the first gate insulating layer 12 has a multilayer structure including the first layer 12a and the second layer 12b, while the second gate insulating layer 22 is provided in the same layer as the second layer 12b of the first gate insulating layer 12, and therefore the second gate insulating layer 22 can have a smaller thickness than the first gate insulating layer 12. Thus, the semiconductor device 100 is advantageous in that the second TFT 20, which is a p-type oxide semiconductor TFT (or p-type transparent semiconductor TFT) of a relatively low mobility, can have a large ON current.

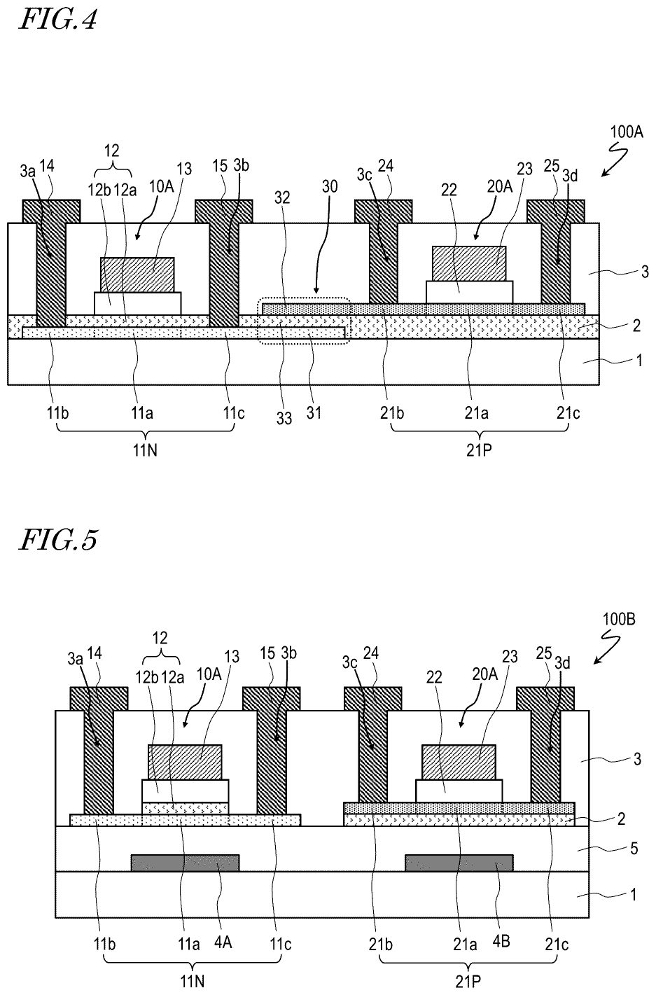

FIG. 4 shows another semiconductor device 100A of the present embodiment. The semiconductor device 100A is different from the configuration of the semiconductor device 100 shown in FIG. 3 in that the semiconductor device 100A includes a capacitive element 30 as shown in FIG. 4.

The capacitive element 30 includes a first capacitive electrode 31, a second capacitive electrode 32, and a capacitive insulating layer 33 provided between the first capacitive electrode 31 and the second capacitive electrode 32.

The first capacitive electrode 31 is an extended part of the first semiconductor layer 11N. In the illustrated example, it can be said that the first capacitive electrode 31 is an extended part of the drain region 11c of the first semiconductor layer 11N and is electrically coupled with the drain region 11c. The first capacitive electrode 31 has reduced resistance (i.e., has electrical conductivity) as the drain region 11c does.

The second capacitive electrode 32 is an extended part of the second semiconductor layer 21P. In the illustrated example, it can be said that the second capacitive electrode 32 is an extended part of the source region 21b of the second semiconductor layer 21P and is electrically coupled with the source region 21b. The second capacitive electrode 32 has reduced resistance (i.e., has electrical conductivity) as the source region 21b does.

The capacitive insulating layer 33 is provided in the same layer as the first layer 12a of the first gate insulating layer 12. In the illustrated example, the capacitive insulating layer 33 is continuous with the first layer 12a of the first gate insulating layer 12 and the insulating layer 2.

When the semiconductor device is used as an active matrix substrate for an organic EL display device as will be described later, each pixel region includes a capacitive element. As in the semiconductor device 100A shown in FIG. 4, the capacitive element 30 can be formed using an extended part of the first semiconductor layer 11N (the first capacitive electrode 31) and an extended part of the second semiconductor layer 21P (the second capacitive electrode 32).

In the example illustrated herein, the first capacitive electrode 31 is an extended part of the drain region 11c of the first semiconductor layer 11N and the second capacitive electrode 32 is an extended part of the source region 21b of the second semiconductor layer 21P, although the first capacitive electrode 31 may be an extended part of the source region 11b of the first semiconductor layer 11N and the second capacitive electrode 32 may be an extended part of the drain region 21c of the second semiconductor layer 21P.

FIG. 5 shows still another semiconductor device 100B of the present embodiment. The semiconductor device 100B is different from the semiconductor device 100 shown in FIG. 1 in that the semiconductor device 100B includes a first light shield layer 4A, a second light shield layer 4B and a lower insulating layer 5 as shown in FIG. 5.

The first light shield layer 4A and the second light shield layer 4B are provided on the substrate 1. The lower insulating layer 5 is provided so as to cover the first light shield layer 4A and the second light shield layer 4B. The first TFT 10A and the second TFT 20A are provided on the lower insulating layer 5.

The first light shield layer 4A underlies the channel region 11a of the first semiconductor layer 11N with the lower insulating layer 5 interposed therebetween. The second light shield layer 4B underlies the channel region 21a of the second semiconductor layer 21P with the lower insulating layer 5 interposed therebetween. Herein, the first light shield layer 4A and the second light shield layer 4B are made of an electrically-conductive material.

When the semiconductor device is used as an active matrix substrate for a liquid crystal display device, provision of the first light shield layer 4A and the second light shield layer 4B as in the semiconductor device 100B shown in FIG. 5 can prevent light from the backlight (illumination device) from reaching the channel regions 11a and 21a.

The first light shield layer 4A and the second light shield layer 4B can be formed by forming an electrically-conductive film for the light shield layer (thickness: for example, 50 nm to 500 nm inclusive) by sputtering or the like and thereafter patterning this electrically-conductive film. As the material of the electrically-conductive film for the light shield layer, for example, the examples previously described as the material of the first electrically-conductive film CF1 can be used.

The lower insulating layer 5 can be formed by, for example, CVD. The thickness of the lower insulating layer 5 is, for example, equal to or greater than 200 nm and equal to or smaller than 500 nm. As the material of the lower insulating layer 5, for example, the examples previously described as the material of the first insulating film IF1 can be used.

The first light shield layer 4A and the second light shield layer 4B may be in an electrically floating state or may be supplied with predetermined potentials. By supplying the first light shield layer 4A and the second light shield layer 4B with predetermined potentials (fixed potentials), the TFT characteristics can be improved. By supplying the first light shield layer 4A with a potential substantially equal to that of the first gate electrode 13, the first light shield layer 4A is allowed to function as the lower gate electrode, and the first TFT 10A may have a double gate structure. Likewise, by supplying the second light shield layer 4B with a potential substantially equal to that of the second gate electrode 23, the second light shield layer 4B is allowed to function as the lower gate electrode, and the second TFT 20A may have a double gate structure.

[Regarding n-Type Oxide Semiconductor]

The oxide semiconductor included in the n-type oxide semiconductor layer may be an amorphous oxide semiconductor or may be a crystalline oxide semiconductor which includes a crystalline portion. Examples of the crystalline oxide semiconductor include a polycrystalline oxide semiconductor, a microcrystalline oxide semiconductor, and a crystalline oxide semiconductor in which the c-axis is oriented generally perpendicular to the layer surface.

The n-type semiconductor layer may have a multilayer structure consisting of two or more layers. The semiconductor layer that has a multilayer structure may include an amorphous oxide semiconductor layer and a crystalline oxide semiconductor layer or may include a plurality of crystalline oxide semiconductor layers having different crystalline structures. The semiconductor layer that has a multilayer structure may include a plurality of amorphous oxide semiconductor layers. When the semiconductor layer has a two-layer structure that includes the upper layer and the lower layer, it is preferred that the energy gap of the oxide semiconductor included in the lower layer is greater than the energy gap of the oxide semiconductor included in the upper layer. Note that, however, when the difference in energy gap between these layers is relatively small, the energy gap of the oxide semiconductor of the upper layer may be greater than the energy gap of the oxide semiconductor of the lower layer.

The materials, structures and film formation methods of the amorphous oxide semiconductor and the respective aforementioned crystalline oxide semiconductors, and the configuration of the oxide semiconductor layer which has a multilayer structure, are disclosed in, for example, Japanese Laid-Open Patent Publication No. 2014-007399. The entire disclosure of Japanese Laid-Open Patent Publication No. 2014-007399 is incorporated by reference in this specification.

The n-type semiconductor layer may include, for example, at least one metal element among In, Ga and Zn. In the present embodiment, the n-type semiconductor layer includes, for example, an In—Ga—Zn—O based semiconductor (e.g., indium gallium zinc oxide). Here, the In—Ga—Zn—O based semiconductor is a ternary oxide including In (indium), Ga (gallium) and Zn (zinc). The proportion (composition ratio) of In, Ga and Zn is not particularly limited but includes, for example, In:Ga:Zn=2:2:1, In:Ga:Zn=1:1:1, and In:Ga:Zn=1:1:2. The semiconductor layer which has such a composition can be formed by an oxide semiconductor film which includes an In—Ga—Zn—O based semiconductor.

The In—Ga—Zn—O based semiconductor may be amorphous or may be crystalline. As the crystalline In—Ga—Zn—O based semiconductor, a crystalline In—Ga—Zn—O based semiconductor in which the c-axis is oriented generally perpendicular to the layer surface is preferred.

The crystalline structure of the crystalline In—Ga—Zn—O based semiconductor is disclosed in, for example, aforementioned Japanese Laid-Open Patent Publication No. 2014-007399, Japanese Laid-Open Patent Publication No. 2012-134475, and Japanese Laid-Open Patent Publication No. 2014-209727. The entire disclosures of Japanese Laid-Open Patent Publication No. 2012-134475 and Japanese Laid-Open Patent Publication No. 2014-209727 are incorporated by reference in this specification. A TFT which includes an In—Ga—Zn—O based semiconductor layer has high mobility (20 times or more as compared with an a-Si TFT) and low current leakage (less than 1/100 as compared with an a-Si TFT).

The n-type semiconductor layer may contain a different oxide semiconductor instead of the In—Ga—Zn—O based semiconductor. For example, the n-type semiconductor layer may contain an In—Sn—Zn—O based semiconductor (e.g., In₂O₃—SnO₂—ZnO; InSnZnO). In—Sn—Zn—O based semiconductor is a ternary oxide including In (indium), Sn (tin) and Zn (zinc). Alternatively, the n-type semiconductor layer may contain an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, a CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, or the like.

[Regarding p-Type Oxide Semiconductor and Transparent Semiconductor]

The oxide semiconductor included in the p-type oxide semiconductor layer may be an amorphous oxide semiconductor or may be a crystalline oxide semiconductor which includes a crystalline portion. The p-type semiconductor layer may have a multilayer structure consisting of two or more layers.

The p-type semiconductor layer can include, for example, SnO (tin oxide), Cu₂O (copper oxide), NiO (nickel oxide), or the like. The p-type semiconductor layer may include a non-oxide transparent semiconductor (e.g., CuI (copper iodide)).

### Embodiment 2

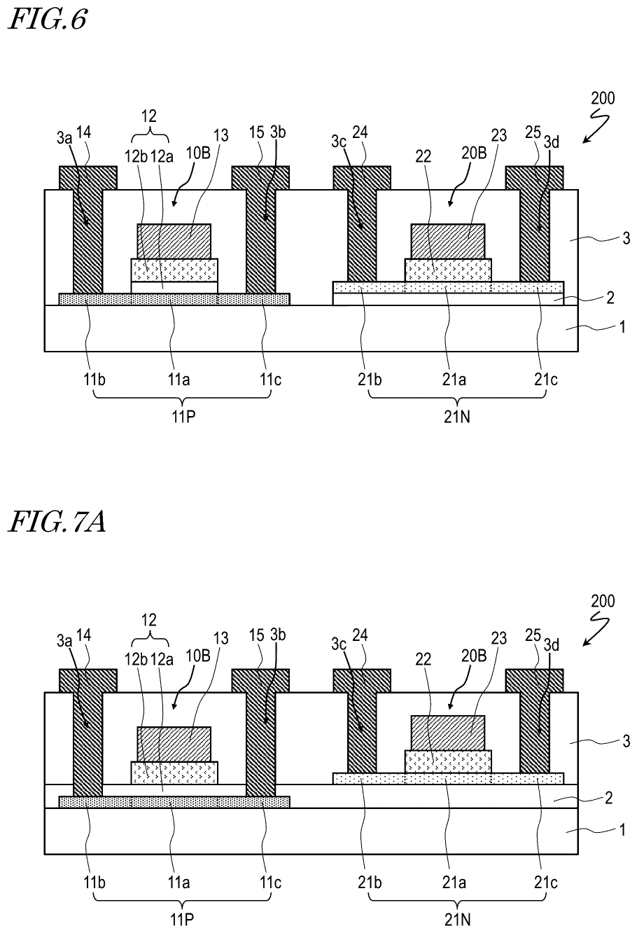

A complementary semiconductor device 200 of the present embodiment is described with reference to FIG. 6. FIG. 6 is a cross-sectional view schematically showing the semiconductor device 200. Hereinafter, the differences of the semiconductor device 200 from the semiconductor device 100 of Embodiment 1 are mainly described.

As shown in FIG. 6, the semiconductor device 200 includes a substrate 1, a first TFT 10B of the first conductivity type, and a second TFT 20B of the second conductivity type that is different from the first conductivity type. In the present embodiment, the first TFT 10B is p-type, and the first semiconductor layer 11P of the first TFT 10B is made of a p-type oxide semiconductor material or a p-type transparent semiconductor material. The second TFT 20B is n-type, and the second semiconductor layer 21N of the second TFT 20B is made of an n-type oxide semiconductor material.

The semiconductor device 200 can be manufactured in substantially the same way as the semiconductor device 100 of Embodiment 1. As the material of the first semiconductor layer 11P, the examples previously described as the material of the second semiconductor layer 21P of the semiconductor device 100 can be used. As the material of the second semiconductor layer 21N, the examples previously described as the material of the first semiconductor layer 11N of the semiconductor device 100 can be used. As the material of the insulating film for formation of the first layer 12a of the first gate insulating layer 12 and the insulating layer 2 (first insulating film), the examples previously described as the material of the second insulating film IF2 shown in, for example, FIG. 2D can be used. As the material of the insulating film for formation of the second layer 12b of the first gate insulating layer 12 and the second gate insulating layer 22 (second insulating film), the examples previously described as the material of the first insulating film IF1 shown in, for example, FIG. 2B can be used.

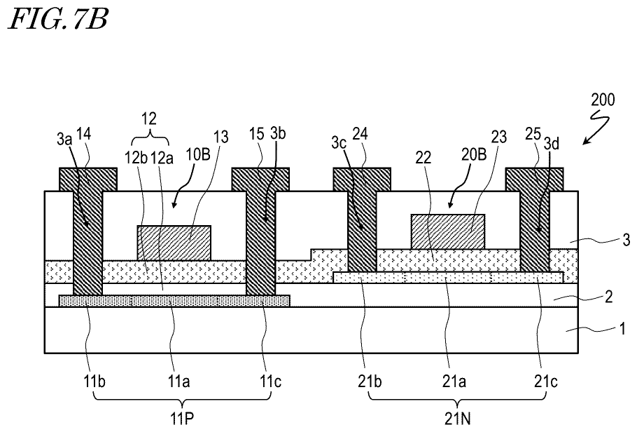

In the example illustrated in FIG. 6, the first layer 12a of the first gate insulating layer 12 and the insulating layer 2 are separated although, as shown in FIG. 7A, the first layer 12a of the first gate insulating layer 12 and the insulating layer 2 may be continuous. With some materials of the first insulating film and the second insulating film or some patterning methods, there is a probability that the first insulating film will not be separated into the first layer 12a of the first gate insulating layer 12 and the insulating layer 2 in the step of patterning the second insulating film. For example, when the first insulating film is an aluminum oxide film and the second insulating film is a silicon oxide film, there is a probability that the first insulating film will not be separated into the first layer 12a of the first gate insulating layer 12 and the insulating layer 2.

Alternatively, as shown in FIG. 7B, none of the first insulating film and the second insulating film may be patterned such that the first layer 12a of the first gate insulating layer 12 and the insulating layer 2 are continuous while the second layer 12b of the first gate insulating layer 12 and the second gate insulating layer 22 are continuous.

As previously described, the semiconductor device 200 of the present embodiment includes the first TFT 10B that is a p-type oxide semiconductor TFT (or p-type transparent semiconductor TFT) and the second TFT 20B that is an n-type oxide semiconductor TFT and, therefore, by using these TFTs in forming a CMOS structure circuit, lower voltages and reduction in power consumption can be achieved. Further, since both the first TFT 10B and the second TFT 20B have a top gate structure, the TFT characteristics and the reliability are excellent. Further, since a part (first layer) 12a of the first gate insulating layer 12 which is in contact with the first semiconductor layer 11P and the second gate insulating layer 22 that is in contact with the second semiconductor layer 21N are formed in different layers, the n-type oxide semiconductor TFT and the p-type oxide semiconductor TFT (or p-type transparent semiconductor TFT) can use different materials in forming the gate insulating films that are in contact with the semiconductor layers, i.e., can employ materials suitable to the respective gate insulating films. Further, the semiconductor device 200 of the present embodiment can be manufactured using a relatively small number of masks and, therefore, the manufacture cost can be reduced.

Further, in the semiconductor device 200 of the present embodiment, the first gate insulating layer 12 has a multilayer structure including the first layer 12a and the second layer 12b. As such, the dielectric breakdown voltage for the first TFT 10B that is the p-type oxide semiconductor TFT (or p-type transparent semiconductor TFT) can be easily secured. For example, when the insulating film that is in contact with the p-type first semiconductor layer 11P (the first layer 12a of the first gate insulating layer 12) is an aluminum oxide film, the aluminum oxide film is deposited by atomic layer deposition (ALD). However, the atomic layer deposition usually progresses at a slow film formation rate and is therefore not suitable to deposition of a thick film. Since the first gate insulating layer 12 has a multilayer structure including the first layer 12a and the second layer 12b, the dielectric breakdown voltage can be easily secured so long as the entirety of the first gate insulating layer 12 is somewhat thick, even if the thickness of the first layer 12a is small.

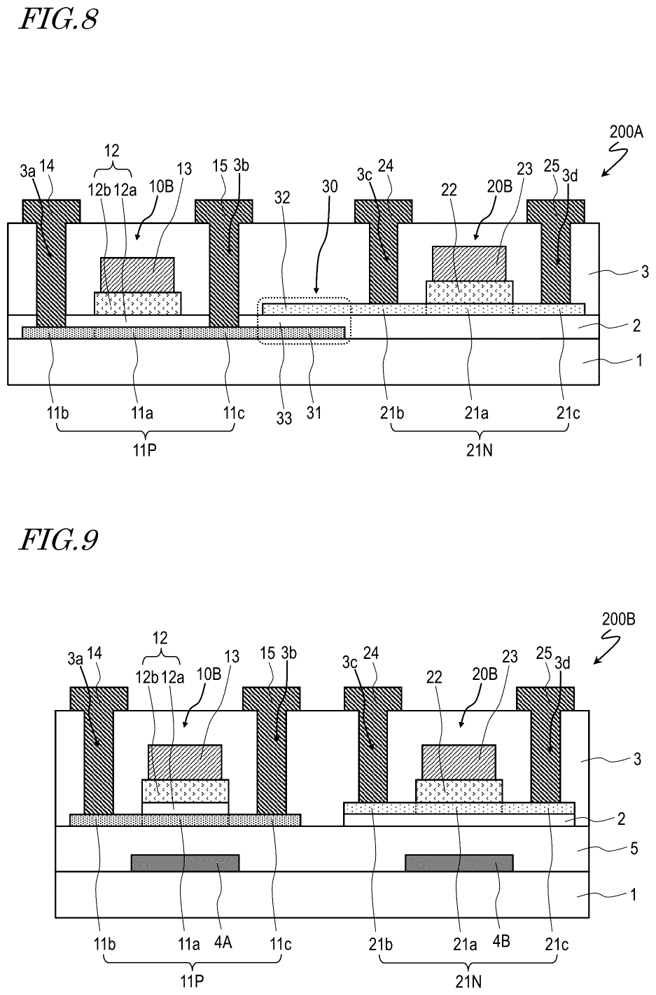

FIG. 8 shows another semiconductor device 200A of the present embodiment. The semiconductor device 200A is different from the configuration of the semiconductor device 200 shown in FIG. 7 in that the semiconductor device 200A includes a capacitive element 30 as shown in FIG. 8.

The capacitive element 30 includes a first capacitive electrode 31, a second capacitive electrode 32, and a capacitive insulating layer 33 provided between the first capacitive electrode 31 and the second capacitive electrode 32.

The first capacitive electrode 31 is an extended part of the first semiconductor layer 11P. In the illustrated example, it can be said that the first capacitive electrode 31 is an extended part of the drain region 11c of the first semiconductor layer 11P and is electrically coupled with the drain region 11c. The first capacitive electrode 31 has reduced resistance (i.e., has electrical conductivity) as the drain region 11c does.

The second capacitive electrode 32 is an extended part of the second semiconductor layer 21N. In the illustrated example, it can be said that the second capacitive electrode 32 is an extended part of the source region 21b of the second semiconductor layer 21N and is electrically coupled with the source region 21b. The second capacitive electrode 32 has reduced resistance (i.e., has electrical conductivity) as the source region 21b does.

The capacitive insulating layer 33 is provided in the same layer as the first layer 12a of the first gate insulating layer 12. In the illustrated example, the capacitive insulating layer 33 is continuous with the first layer 12a of the first gate insulating layer 12 and the insulating layer 2.

When the semiconductor device is used as an active matrix substrate for an organic EL display device as will be described later, each pixel region includes a capacitive element. As in the semiconductor device 200A shown in FIG. 8, the capacitive element 30 can be formed using an extended part of the first semiconductor layer 11P (the first capacitive electrode 31) and an extended part of the second semiconductor layer 21N (the second capacitive electrode 32).

Some of the examples described as the material of the insulating film for formation of the first layer 12a of the first gate insulating layer 12 (first insulating film), e.g., aluminum oxide, have higher relative permittivity than silicon oxide or the like. When such a material is used, the area of the capacitive element 30 can be reduced.

In the example illustrated herein, the first capacitive electrode 31 is an extended part of the drain region 11c of the first semiconductor layer 11P and the second capacitive electrode 32 is an extended part of the source region 21b of the second semiconductor layer 21N, although the first capacitive electrode 31 may be an extended part of the source region 11b of the first semiconductor layer 11P and the second capacitive electrode 32 may be an extended part of the drain region 21c of the second semiconductor layer 21N.

FIG. 9 shows still another semiconductor device 200B of the present embodiment. The semiconductor device 200B is different from the semiconductor device 200 shown in FIG. 6 in that the semiconductor device 200B includes a first light shield layer 4A, a second light shield layer 4B, and a lower insulating layer 5 as shown in FIG. 9.

The first light shield layer 4A and the second light shield layer 4B are provided on the substrate 1. The lower insulating layer 5 is provided so as to cover the first light shield layer 4A and the second light shield layer 4B. The first TFT 10B and the second TFT 20B are provided on the lower insulating layer 5.

The first light shield layer 4A underlies the channel region 11a of the first semiconductor layer 11P with the lower insulating layer 5 interposed therebetween. The second light shield layer 4B underlies the channel region 21a of the second semiconductor layer 21N with the lower insulating layer 5 interposed therebetween. Herein, the first light shield layer 4A and the second light shield layer 4B are made of an electrically-conductive material.

When the semiconductor device is used as an active matrix substrate for a liquid crystal display device, provision of the first light shield layer 4A and the second light shield layer 4B as in the semiconductor device 200B shown in FIG. 9 can prevent light from the backlight (illumination device) from reaching the channel regions 11a and 21a.

The first light shield layer 4A and the second light shield layer 4B may be in an electrically floating state or may be supplied with predetermined potentials. By supplying the first light shield layer 4A and the second light shield layer 4B with predetermined potentials (fixed potentials), the TFT characteristics can be improved. By supplying the first light shield layer 4A with a potential substantially equal to that of the first gate electrode 13, the first light shield layer 4A is allowed to function as the lower gate electrode, and the first TFT 10B may have a double gate structure. Likewise, by supplying the second light shield layer 4B with a potential substantially equal to that of the second gate electrode 23, the second light shield layer 4B is allowed to function as the lower gate electrode, and the second TFT 20B may have a double gate structure.

[Active Matrix Substrate]

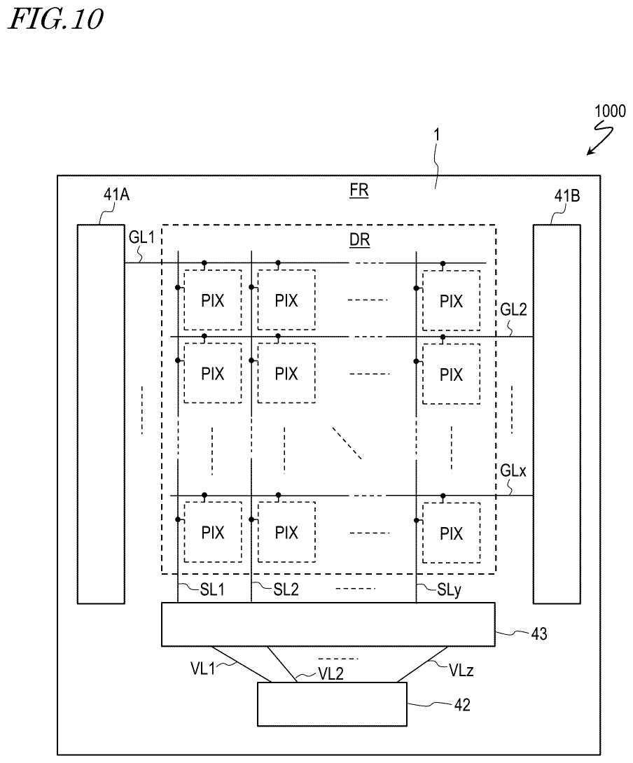

A semiconductor device according to an embodiment of the present invention can be suitably used as, for example, an active matrix substrate for display devices. The configuration of an active matrix substrate 1000 is described with reference to FIG. 10.

The active matrix substrate 1000 can be, for example, any one of the above-described semiconductor devices 100, 100A, 100B, 200, 200A, 200B. The active matrix substrate 1000 includes a display region DR and a peripheral region FR as shown in FIG. 10.

The display region DR includes a plurality of pixel regions PIX. The pixel regions PIX correspond to the pixels of the display device. Hereinafter, the pixel regions PIX are sometimes simply referred to as “pixels”. The plurality of pixel regions PIX are arrayed in a matrix including a plurality of rows and a plurality of columns. The display region DR is defined by the plurality of pixel regions PIX arrayed in a matrix.

The peripheral region FR lies around the display region DR. The peripheral region FR does not contribute to displaying and is also referred to as “non-display region” or “frame region”.

On the substrate 1, a plurality of gate bus lines (scan lines) GL and a plurality of source bus lines (signal lines) SL are provided. Each of the gate bus lines GL extends along a row direction. Each of the source bus lines SL extends along a column direction. In FIG. 10, the gate bus lines GL of the first, second, . . . and x^{th} rows are indicated with “GL1”, “GL2”, . . . and “GLx”, and the source bus lines SL of the first, second, . . . and y^{th} columns are indicated with “SL1”, “SL2”, . . . and “SLy”. Typically, a region surrounded by two adjacent gate bus lines GL and two adjacent source bus lines SL is a pixel region PIX.

In the peripheral region FR, gate driver circuits 41A and 41B for driving the gate bus lines GL, a source driver circuit 42 for driving the source bus lines SL, and a demultiplexer (DEMUX) circuit 43 are provided. The DEMUX circuit 43 functions as an SSD circuit that drives the source bus lines SL in a time division manner. Herein, the gate driver circuits 41A and 41B are integrally (monolithically) formed on the substrate 1 (hereinafter, also referred to as GDM (Gate Driver Monolithic) circuit). The DEMUX circuit 43 is monolithically formed on the substrate 1 as the gate driver circuits 41A and 41B are. The source driver circuit 42 is mounted (e.g., COG-mounted) to the substrate 1.

In the illustrated example, the gate driver circuit 41A for driving the gate bus lines GL of the odd-numbered rows is located on the left side of the display region DR while the gate driver circuit 41B for driving the gate bus lines GL of the even-numbered rows is located on the right side of the display region DR. Each of a plurality of output terminals (not shown) of the gate driver circuit 41A is connected with a corresponding one of the gate bus lines GL of the odd-numbered rows. Each of a plurality of output terminals (not shown) of the gate driver circuit 41B is connected with a corresponding one of the gate bus lines GL of the even-numbered rows.

The source driver circuit 42 is located on the lower side of the display region DR, and the DEMUX circuit 43 is located between the source driver circuit 42 and the display region DR. The source driver circuit 42 has a plurality of output terminals (not shown). In a region between the source driver circuit 42 and the DEMUX circuit 43, a plurality of signal output lines (video signal lines) VL are provided. Each of the plurality of signal output lines VL is connected with a corresponding one of the plurality of output terminals of the source driver circuit 42. In FIG. 10, the first, second, . . . and z^{th} signal output lines VL are indicated with “VL1”, “VL2”, . . . and “VLz”.

The DEMUX circuit 43 distributes a display signal supplied from a single signal output line VL to two or more source bus lines SL.

When, in the active matrix substrate 1000, the GDM circuits 41A and 41B include a CMOS structure circuit in which the first TFT 10A and the second TFT 20A (or the first TFT 10B and the second TFT 20B) are used, reduction in power consumption can be achieved. Also, when the DEMUX circuit 43 includes a CMOS structure circuit in which the first TFT 10A and the second TFT 20A (or the first TFT 10B and the second TFT 20B) are used, the voltage of the switching signals can be decreased, so that reduction in power consumption and improvement in reliability can be achieved.

The active matrix substrate 1000 can be used in various types of display devices. The active matrix substrate 1000 can be suitably used in, for example, a liquid crystal display device or an organic EL display device.

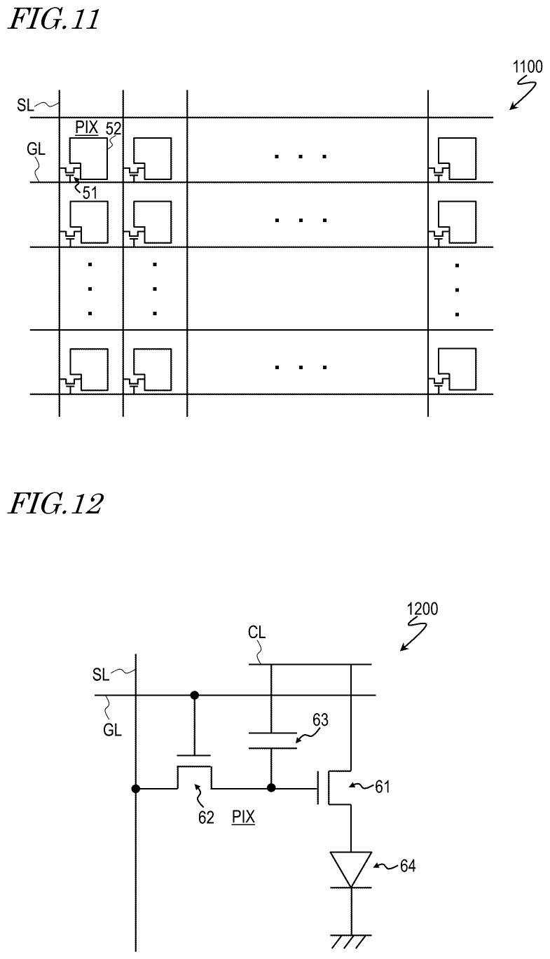

FIG. 11 is an example of the equivalent circuit diagram of a plurality of pixels PIX included in a liquid crystal display device 1100. Although not shown herein, the liquid crystal display device 1100 includes an active matrix substrate 1000, a counter substrate located opposite to the active matrix substrate 1000, and a liquid crystal layer interposed between the active matrix substrate 1000 and the counter substrate.

In each of the pixels PIX of the liquid crystal display device 1100, a pixel TFT 51 and a pixel electrode 52 are provided as shown in FIG. 11. The gate electrode, the source electrode and the drain electrode of the pixel TFT 51 are electrically coupled with a gate bus line GL, a source bus line SL and the pixel electrode 52, respectively. As the pixel TFT 51, an n-type oxide semiconductor TFT (the first TFT 10A or the second TFT 20B) can be suitably used.

FIG. 12 is an example of the equivalent circuit diagram of a single pixel PIX of an organic EL display device 1200. Although not shown herein, the organic EL display device 1200 at least includes an active matrix substrate 1000.

In each of the pixels PIX of the organic EL display device 1200, a driver TFT 61, a selector TFT 62, a capacitive element (storage capacitance) 63, and an OLED (organic light-emitting diode) 64 are provided. Although not shown herein, the OLED 64 is formed by a pixel electrode (e.g., anode), an organic EL layer provided on the pixel electrode, and a common electrode (e.g., cathode) provided on the organic EL layer.

The gate electrode and the source electrode of the selector TFT 62 are electrically coupled with a gate bus line GL and a source bus line SL, respectively. The drain electrode of the selector TFT 62 is electrically coupled with the gate electrode of the driver TFT 61 and the capacitive element 63. The drain electrode of the driver TFT 61 is electrically coupled with a power supply line CL. The source electrode of the driver TFT 61 is electrically coupled with the OLED 64, more specifically with the pixel electrode of the OLED 64.

As the driver TFT 61, a p-type oxide semiconductor TFT or a p-type transparent semiconductor TFT (the second TFT 20A or the first TFT 10B) can be suitably used. As the selector TFT 62, an n-type oxide semiconductor TFT (the first TFT 10A or the second TFT 20B) can be suitably used.

From the above-described oxide semiconductor TFT (or transparent semiconductor TFT), the drain electrode may be omitted. For example, the drain electrode of the pixel TFT 51 of the liquid crystal display device 1100 may be omitted such that the pixel electrode 52 is directly connected with the drain region of the semiconductor layer of the pixel TFT 51.

According to an embodiment of the present invention, a CMOS structure can be suitably realized in which an n-type oxide semiconductor TFT and a p-type oxide semiconductor TFT (or p-type transparent semiconductor TFT) are used. A semiconductor device according to an embodiment of the present invention can be used as an active matrix substrate in various types of display devices and, for example, can be suitably used as an active matrix substrate in a liquid crystal display device or an organic EL display device.

This application is based on U.S. Provisional Application No. 63/423,581 filed on Nov. 8, 2022, the entire contents of which are hereby incorporated by reference.

What is claimed is:

1. A complementary semiconductor device comprising:
a substrate;
a first thin film transistor of a first conductivity type, the first thin film transistor being supported by the substrate; and
a second thin film transistor of a second conductivity type that is different from the first conductivity type, the second thin film transistor being supported by the substrate,
wherein the first thin film transistor includes
a first semiconductor layer made of an oxide semiconductor material of the first conductivity type, the first semiconductor layer including a first channel region and a first source region and a first drain region located on opposite sides of the first channel region,
a first gate insulating layer provided on the first semiconductor layer,
a first gate electrode located opposite to the first channel region with the first gate insulating layer interposed therebetween, and
a first source electrode electrically coupled with the first source region,
wherein the second thin film transistor includes
a second semiconductor layer made of an oxide semiconductor material of the second conductivity type or a transparent semiconductor material of the second conductivity type, the second semiconductor layer including a second channel region and a second source region and a second drain region located on opposite sides of the second channel region,
a second gate insulating layer provided on the second semiconductor layer,
a second gate electrode located opposite to the second channel region with the second gate insulating layer interposed therebetween, and
a second source electrode electrically coupled with the second source region,
wherein the first gate insulating layer includes a first layer and a second layer provided on the first layer, and
wherein the second layer of the first gate insulating layer and the second gate insulating layer are provided in the same layer.

2. The semiconductor device of claim 1, wherein
the first gate electrode and the second gate electrode are provided in the same layer, and
the first source electrode and the second source electrode are provided in the same layer.

3. The semiconductor device of claim 1 further comprising an insulating layer provided in the same layer as the first layer of the first gate insulating layer,
wherein the second semiconductor layer is provided on the insulating layer.

4. The semiconductor device of claim 1, wherein
the first thin film transistor includes a first drain electrode electrically coupled with the first drain region,
the second thin film transistor includes a second drain electrode electrically coupled with the second drain region,
the first source electrode, the first drain electrode, the second source electrode and the second drain electrode are provided in the same layer.

5. The semiconductor device of claim 4 further comprising an interlayer insulating layer provided so as to cover the first gate electrode and the second gate electrode,
wherein the first source electrode, the first drain electrode, the second source electrode and the second drain electrode are provided on the interlayer insulating layer.

6. The semiconductor device of claim 1, wherein the first conductivity type is n-type, and the second conductivity type is p-type.

7. The semiconductor device of claim 6, wherein the first semiconductor layer includes an In—Ga—Zn—O based semiconductor.

8. The semiconductor device of claim 1, wherein the first conductivity type is p-type, and the second conductivity type is n-type.

9. The semiconductor device of claim 8, wherein the second semiconductor layer includes an In—Ga—Zn—O based semiconductor.

10. The semiconductor device of claim 1 further comprising a capacitive element, the capacitive element including
a first capacitive electrode that is an extended part of the first semiconductor layer,
a second capacitive electrode that is an extended part of the second semiconductor layer, and
a capacitive insulating layer provided between the first capacitive electrode and the second capacitive electrode, the capacitive insulating layer being provided in the same layer as the first layer of the first gate insulating layer.

11. The semiconductor device of claim 1, wherein the semiconductor device is an active matrix substrate for a display device that includes a display region defined by a plurality of pixel regions and a peripheral region lying around the display region.

12. The semiconductor device of claim 11 further comprising a gate driver circuit provided in the peripheral region,
wherein the gate driver circuit includes the first thin film transistor and the second thin film transistor.

13. The semiconductor device of claim 11 further comprising a demultiplexer circuit provided in the peripheral region,
wherein the demultiplexer circuit includes the first thin film transistor and the second thin film transistor.

14. A display device comprising the semiconductor device of claim 11 as the active matrix substrate.

15. The display device of claim 14, wherein the display device is a liquid crystal display device.

16. The display device of claim 14, wherein the display device is an organic EL display device.

17. A method of manufacturing a complementary semiconductor device, the complementary semiconductor device including
a substrate,
a first thin film transistor of a first conductivity type, the first thin film transistor being supported by the substrate, and
a second thin film transistor of a second conductivity type that is different from the first conductivity type, the second thin film transistor being supported by the substrate,
the first thin film transistor including
a first semiconductor layer made of an oxide semiconductor material of the first conductivity type, the first semiconductor layer including a first channel region and a first source region and a first drain region located on opposite sides of the first channel region,
a first gate insulating layer provided on the first semiconductor layer,
a first gate electrode located opposite to the first channel region with the first gate insulating layer interposed therebetween, and
a first source electrode electrically coupled with the first source region, and
the second thin film transistor including
a second semiconductor layer made of an oxide semiconductor material of the second conductivity type or a transparent semiconductor material of the second conductivity type, the second semiconductor layer including a second channel region and a second source region and a second drain region located on opposite sides of the second channel region,
a second gate insulating layer provided on the second semiconductor layer,
a second gate electrode located opposite to the second channel region with the second gate insulating layer interposed therebetween, and
a second source electrode electrically coupled with the second source region,
the method comprising:
(A) depositing a first semiconductor film on the substrate and thereafter patterning the first semiconductor film, thereby forming the first semiconductor layer;
(B) after (A), depositing a first insulating film so as to cover the first semiconductor layer, the first insulating film including a region which is to become a first layer that is a part of the first gate insulating layer;
(C) after (B), depositing a second semiconductor film and thereafter patterning the second semiconductor film, thereby forming the second semiconductor layer;
(D) after (C), depositing a second insulating film, the second insulating film including a region which is to become a second layer that is another part of the first gate insulating layer and a region which is to become the second gate insulating layer;
(E) after (D), depositing a first electrically-conductive film and thereafter patterning the first electrically-conductive film, thereby forming the first gate electrode and the second gate electrode;
(F) after (E), forming an interlayer insulating layer so as to cover the first gate electrode and the second gate electrode; and
(G) after (F), depositing a second electrically-conductive film on the interlayer insulating layer and thereafter patterning the second electrically-conductive film, thereby forming the first source electrode and the second source electrode.

18. The method of claim 17, wherein
the first thin film transistor includes a first drain electrode electrically coupled with the first drain region,
the second thin film transistor includes a second drain electrode electrically coupled with the second drain region, and
(G) includes forming the first drain electrode and the second drain electrode together with the first source electrode and the second source electrode.

19. The method of claim 17, wherein the first conductivity type is n-type, and the second conductivity type is p-type.

20. The method of claim 17, wherein the first conductivity type is p-type, and the second conductivity type is n-type.
